(19) United States
(12) Patent Application Publication
(10) Pub. No.: US 2023/0324082 A1
(43) Pub. Date: Oct. 12, 2023

(54) POSITIVE DISPLACEMENT MACHINE, COMPRESSOR, COOLING APPARATUS, AND ELECTRONIC EQUIPMENT

(71) Applicant: SEIKO EPSON CORPORATION, Tokyo (JP)

(72) Inventors: Osamu KATSUDA, Matsumoto-shi (JP); Kaname NAGATANI, Matsumoto-shi (JP); Hidemasa YAMAKAWA, Matsumoto-shi (JP); Tomoki ABE, Matsumoto-shi (JP)

(21) Appl. No.: 18/192,808

(22) Filed: Mar. 30, 2023

(30) Foreign Application Priority Data
Mar. 30, 2022 (JP) 2022-055324

(51) Int. Cl. H02K 5/26; H05K 7/20; F04B 35/04; F25B 1/02

(52) U.S. Cl. CPC F25B 1/02; F04B 35/04; H02K 5/26; H05K 7/20009

(57) ABSTRACT

A positive displacement machine includes a housing including a guide part, a slide member including a piston disposed in the guide part, a coupling member coupled to the slide member, a first rotating member coupled to the coupling member and configured to rotate centering on a first rotation axis, a second rotating member coupled to the coupling member and configured to rotate, centering on a second rotation axis, in an opposite direction of a rotating direction of the first rotating member, and a first motor including a first rotor coupled to the first rotating member and a first stator disposed on an outer side of the first rotor, The first motor includes a first adjusting mechanism configured to adjust an angle of the first stator with respect to the first rotor, the angle being centered on the first rotation axis.

The present application is based on, and claims priority from JP Application Serial Number 2022-055324, filed Mar. 30, 2022, the disclosure of which is hereby incorporated by reference herein in its entirety.

### BACKGROUND

### 1. Technical Field

The present disclosure relates to a positive displacement machine, a compressor, a cooling apparatus, and electronic equipment.

### 2. Related Art

There has been known a positive displacement machine used in a compressor for refrigeration air conditioning, an internal combustion engine for generator driving, and the like (see, for example, JP-A-9-072275 (Patent Literature 1)).

The positive displacement machine described in Patent Literature 1 is a hermetic compressor. The hermetic compressor includes a reciprocating member including two pistons, a cylinder block, two arms, two spherical bushes, two driving shafts including driving arms, and two driving motors. The two pistons are supported by the inner circumferential cylindrical surface of the cylinder block to be capable of implementing reciprocation and a swinging motion around an axis in a reciprocating direction. Each of the two arms is rotatably inserted into an inner circumferential cylindrical surface of the spherical bush corresponding to the arm. Outer circumferential spherical surfaces of the spherical bushes are supported in positions displaced from rotation axes of the driving shafts by the driving arms of the driving shafts corresponding to the spherical bushes.

In such a hermetic compressor, the two driving arms are rotated in opposite directions each other around the driving shafts by the two driving motors and the two arms coupled to the driving arms via the spherical bushes move in the reciprocating direction, whereby the reciprocating member reciprocates in the cylinder block. Consequently, the pistons swing while reciprocating on the inner circumferential cylindrical surface of the cylinder block, whereby working fluid flowing into a workspace is compressed and thereafter discharged to the outside.

In the positive displacement machine described in Patent Literature 1, since the two driving motors rotate the driving shafts in opposite directions each other, vibration at the driving time of the positive displacement machine is reduced. However, there has been a demand for a configuration capable of further reducing vibration that occurs in the positive displacement machine.

For example, it is conceivable to attach the driving motors in positions where vibration that occurs at the driving time of the two driving motors is reduced.

However, since the positive displacement machine described in Patent Literature 1 does not include a configuration capable of adjusting the positions of the driving motors, attachment flexibility of the driving motors is low and it is difficult to achieve a reduction in vibration.

### SUMMARY

A positive displacement machine according to a first aspect of the present disclosure includes: a housing including a tubular guide part in which a pressure chamber is provided; a slide member including a piston disposed in the guide part, the slide member sliding in a first direction; a coupling member coupled to the slide member and extending in a second direction intersecting the first direction; a first rotating member coupled to one end portion of the coupling member and configured to rotate centering on a first rotation axis extending in the second direction; a second rotating member coupled to another end of the coupling member and configured to rotate, centering on a second rotation axis extending along the second direction, in an opposite direction of a rotating direction of the first rotating member; a first motor including a first rotor coupled to the first rotating member and configured to rotate centering on the first rotation axis and a first stator disposed on an outer side of the first rotor when viewed along the first rotation axis; and a second motor including a second rotor coupled to the second rotating member and configured to rotate centering on the second rotation axis and a second stator disposed on an outer side of the second rotor when viewed along the second rotation axis. The first motor includes a first adjusting mechanism configured to adjust an angle of the first stator with respect to the first rotor, the angle being centered on the first rotation axis.

A compressor according to a second aspect of the present disclosure includes the positive displacement machine according to the first aspect. The piston compresses gas flowing into the pressure chamber.

A cooling apparatus according to a third aspect of the present disclosure includes: the compressor according to the second aspect configured to compress working fluid in a gas phase; a condenser configured to condense the working fluid in the gas phase compressed by the compressor into the working fluid in a liquid phase; an expander configured to decompress the working fluid in the liquid phase condensed by the condenser and change the working fluid in the liquid phase to the working fluid to a state in which the liquid phase and the gas phase are mixed; and an evaporator coupled to a cooling target to transfer heat, the evaporator being configured to change the working fluid flowing from the expander to the working fluid in the gas phase with the heat transferred from the cooling target and discharge the changed working fluid in the gas phase to the compressor.

Electronic equipment according to a fourth aspect of the present disclosure includes the cooling apparatus according to the third aspect.

### BRIEF DESCRIPTION OF THE DRAWINGS

FIG. 1 is a block diagram showing a configuration of electronic equipment in an embodiment.

FIG. 2 is a sectional view showing a compressor in the embodiment.

FIG. 3 is a schematic diagram showing a cross section of a first motor according to the embodiment.

FIG. 4 is a flowchart showing a method of attaching motors according to the embodiment.

FIG. 5 is a perspective view showing the first motor attached to a housing according to the embodiment.

FIG. 6 is a side view showing the first motor according to the embodiment.

FIG. 7 is a block diagram showing another configuration of a positive displacement machine according to the embodiment.

### DESCRIPTION OF EXEMPLARY EMBODIMENT

An embodiment of the present disclosure is explained below with reference to the drawings.

### Configuration of Electronic Equipment

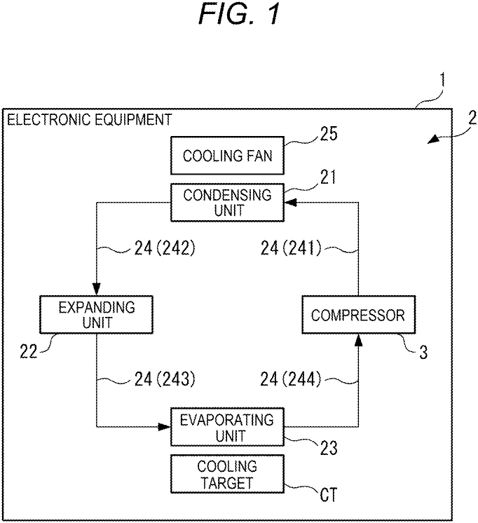

FIG. 1 is a block diagram showing a configuration of electronic equipment 1 according to this embodiment.

The electronic equipment 1 according to this embodiment includes a cooling target CT and a cooling apparatus 2 as shown in FIG. 1.

The cooling target CT configures the electronic equipment 1. Examples of the cooling target CT include a control device that controls the electronic equipment 1 and a power supply device that supplies electric power to electronic components of the electronic equipment 1.

### Configuration of the Cooling Apparatus

The cooling apparatus 2 cools the cooling target CT. Specifically, the cooling apparatus 2 circulates working fluid, which changes in phase between a liquid phase and a gas phase, and cools the cooling target CT.

The colling device 2 includes a compressor 3, a condenser 21, an expander 22, an evaporator 23, a plurality of pipes 24, and a cooling fan 25.

### Schematic Configuration of the Compressor

The compressor 3 compresses the working fluid in the gas phase. That is, the compressor 3 compresses the working fluid in the gas phase flowing in from the evaporator 23 to thereby increase the temperature and the pressure of the working fluid in the gas phase. The working fluid in the gas phase increased in the temperature and the pressure by the compressor 3 flows to the condenser 21.

A configuration of the compressor 3 is explained in detail below.

### Configuration of the Condenser

The condenser 21 is coupled to the compressor 3 via the pipe 24. The condenser 21 condenses the working fluid in the gas phase compressed by the compressor 3, that is, the working fluid in the gas phase increased in the temperature and the pressure into the working fluid in the liquid phase. Specifically, the condenser 21 exchanges heat between the compressed working fluid in the gas phase and the cooling gas circulated to the condenser 21 by the cooling fan 25 to thereby condense the working fluid in the gas phase into the working fluid in the liquid phase having high pressure.

### Configuration of the Expander

The expander 22 is a decompressor and is coupled to the condenser 21. The expander 22 decompresses the working fluid in the liquid phase condensed by the condenser 21 and changes a state of the working fluid to a state in which the liquid phase and the gas phase are mixed. That is, the expander 22 reduces the temperature of the working fluid. The expander 22 discharges, to the evaporator 23, the working fluid in the state in which the liquid phase and the gas phase are mixed. The expander 22 can be configured by, for example, an expansion valve capable of controlling an evaporation temperature of the working fluid in the liquid phase, specifically, an electronic expansion valve, and can be configured by a capillary tube.

### Configuration of the Evaporator

The evaporator 23 is coupled to the cooling target CT to be capable of transferring heat. The evaporator 23 evaporates, with the heat transferred from the cooling target CT, the working fluid in the liquid phase flowing from the expander 22, changes the working fluid in the liquid phase to the working fluid in the gas phase, and discharges the changed working fluid in the gas phase to the compressor 3. Consequently, the heat of the cooling target CT is consumed and the cooling target CT is cooled.

### Configuration of the Plurality of Pipes

The plurality of pipes 24 annularly couple the compressor 3, the condenser 21, the expander 22, and the evaporator 23. The plurality of pipes 24 are tubular members in which the working fluid can flow.

The plurality of pipes 24 include a first pipe 241, a second pipe 242, a third pipe 243, and a fourth pipe 244.

The first pipe 241 couples the compressor 3 and the condenser 21.

The second pipe 242 couples the condenser 21 and the expander 22.

The third pipe 243 couples the expander 22 and the evaporator 23.

The fourth pipe 244 couples the evaporator 23 and the compressor 3.

In this way, the cooling apparatus 2 includes a circulation path of the working fluid that flows through the compressor 3, the first pipe 241, the condenser 21, the second pipe 242, the expander 22, the third pipe 243, the evaporator 23, and the fourth pipe 244 in order and flows into the compressor 3 again. The circulation path cools the cooling target CT.

### Detailed Configuration of the Compressor

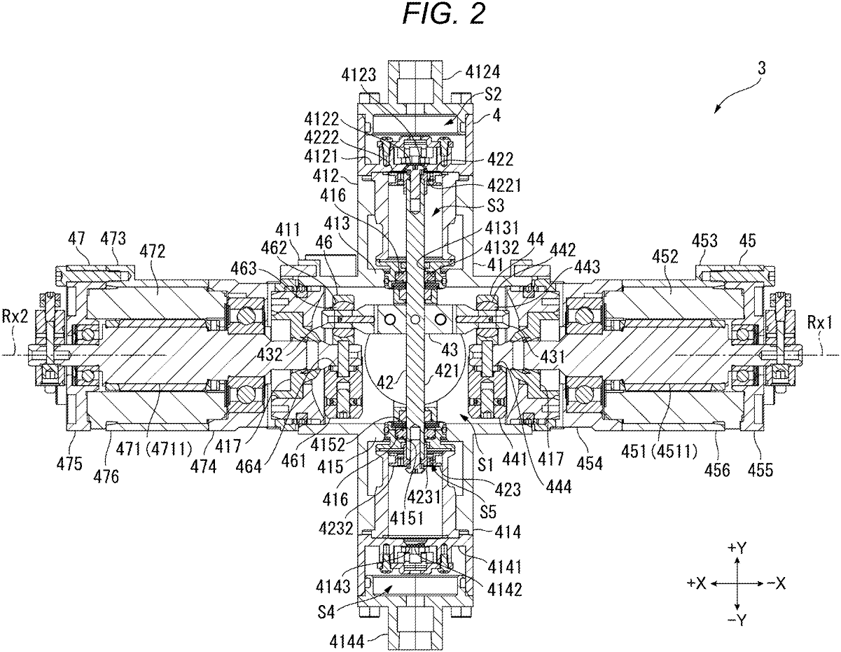

FIG. 2 is a sectional view showing the compressor 3.

As explained above, the compressor 3 compresses the working fluid in the gas phase flowing in from the evaporator 23 and discharges the working fluid to the condenser 21. Specifically, the compressor 3 is a reciprocating compressor that compresses the working fluid in the gas phase that is gas flowing into a first pressure chamber S2 and a second pressure chamber S4 explained below according to reciprocation of a first piston 422 and a second piston 423 of a slide member 42 explained below. The compressor 3 includes a positive displacement machine 4 as shown in FIG. 2.

### Configuration of the Positive Displacement Machine

The positive displacement machine 4 includes a housing 41, a slide member 42, a coupling member 43, a first rotating member 44, a first motor 45, a second rotating member 46, and a second motor 47.

In the following explanation, two directions orthogonal to each other are represented as a +X direction and a +Y direction. The +X direction is a direction extending along a rotation axis Rx1 of the first motor 45 or a rotation axis Rx2 of the second motor 47 explained below and extending from the first motor 45 toward the second motor 47. That is, the left direction when viewed in FIG. 2 is the +X direction. The +Y direction is a direction extending along a reciprocating direction of the slide member 42 and extending from the second piston 423 toward the first piston 422 included in the side member 42. That is, the upward direction when viewed in FIG. 2 is the +Y direction. The +Y direction is a direction crossing the rotation axes Rx1 and Rx2.

Further, the opposite direction of the +X direction is represented as a -X direction and the opposite direction of the +Y direction is represented as a -Y direction. That is, the right direction when viewed in FIG. 2 is the -X direction and the downward direction when viewed in FIG. 2 is the -Y direction.

In this embodiment, the +X direction or the -X direction is equivalent to the second direction and the +Y direction or the -Y direction is equivalent to the first direction.

### Configuration of the Housing

The housing 41 is a housing that houses main components of the positive displacement machine 4 and to which the motors 45 and 47 are attached. The housing 41 configures the exterior of the positive displacement machine 4. The housing 41 includes a housing part 411, a first guide part 412, a first segmenting part 413, a second guide part 414, a second segmenting part 415, two first sealing members 416, and two second sealing members 417.

### Configuration of the Housing Part

The housing part 411 is a housing main body in which a mechanism chamber S1 is provided, a part of the slide member 42, the coupling member 43, the first rotating member 44, a part of the first motor 45, the second rotating member 46, and a part of the second motor 47 being housed on the inside of the mechanism chamber S1.

The mechanism chamber S1 includes lubricant on the inside. In other words, the housing 41 includes the lubricant encapsulated in the mechanism chamber S1. In this embodiment, an amount of the lubricant is approximately a half of the capacity of the mechanism chamber S1. However, the amount of the lubricant is not limited to this and can be changed as appropriate.

### Configuration of the First Guide Part

The first guide part 412 is formed in a cylindrical shape and projects in the +Y direction from the housing part 411. The first piston 422 is disposed on the inside of the first guide part 412. The first guide part 412 guides the reciprocation of the first piston 422 in the +Y direction.

The first pressure chamber S2 and a first working chamber S3 are provided on the inside of the first guide part 412.

The first pressure chamber S2 is a space in the +Y direction for the first piston 422 in a space on the inside of the first guide part 412. That is, the first pressure chamber S2 is a space provided in the first guide part 412, the capacity of the first pressure chamber S2 changing according to the slide of the first piston 422.

The first working chamber S3 is a space in the -Y direction for the first piston 422 in the space on the inside of the first guide part 412. That is, the first working chamber S3 is a space provided between the mechanism chamber S1 and the first pressure chamber S2 on the inside of the first guide part 412 and is divided from the first pressure chamber S2 by the first piston 422. A space between the mechanism chamber S1 and the first working chamber S3 is sealed by the one of the two first sealing members 416.

The first guide part 412 includes a first partition wall 4121, a first discharge valve 4123, and a first outflow part 4124.

The first partition wall 4121 segments the first pressure chamber S2 into a first suction chamber, which is a space in the -Y direction, and a first high-pressure chamber, which is a space in the +Y direction. A through-hole 4122 piecing through the first partition wall 4121 in the +Y direction is provided in the first partition wall 4121. The first suction chamber and the first high-pressure chamber communicate via the through-hole 4122. The working fluid in the gas phase is supplied to the first suction chamber from the first working chamber S3 via a channel 4221 of the first piston 422.

The first discharge valve 4123 opens when the pressure in the first suction chamber is higher than the pressure in the first high-pressure chamber.

The first outflow part 4124 is provided in a portion on the first high-pressure chamber side in the first guide part 412. The first outflow part 4124 is coupled to the first pipe 241 (see FIG. 1).

A part of the working fluid flows into a space in the first guide part 412 and is supplied into the first suction chamber via the channel 4221 and a suction valve 4222 of the first piston 422 by the reciprocation of the first piston 422. Thereafter, the working fluid in the gas phase flows into the first high-pressure chamber from the first suction chamber via the first discharge valve 4123 while being compressed by the first piston 422 and flows out to the first pipe 241 from the first outflow part 4124.

### Configuration of the First Segmenting Part

The first segmenting part 413 is a segmenting part that is provided in a coupling portion of the housing part 411 and the first guide part 412 and segments the mechanism chamber S1 and the first working chamber S3. The first segmenting part 413 projects in the inner diameter direction from a portion on the first guide part 412 side in the housing part 411. The first segmenting part 413 includes a communication hole 4131 and a disposing part 4132.

The communication hole 4131 pierces through the first segmenting part 413 in the +Y direction. A rod 421 of the slide member 42 is inserted through the communication hole 4131 in the +Y direction. That is, the first working chamber S3 is connected to the mechanism chamber S1 via the communication hole 4131.

The disposing part 4132 is a portion where the one of the two first sealing members 416 is disposed in the first segmenting part 413.

### Configuration of the Second Guide Part

The second guide part 414 is formed in a cylindrical shape and projects in the -Y direction from the housing part 411. The second piston 423 is disposed on the inside of the second guide part 414. The second guide part 414 guides reciprocation in the +Y direction of the second piston 423.

A second pressure chamber S4 and a second working chamber S5 are provided on the inside of the second guide part 414.

The second pressure chamber S4 is a space in the -Y direction for the second piston 423 in a space on the inside of the second guide part 414. That is, the second pressure chamber S4 is a space provided in the second guide part 414, the capacity of the space changing according to the slide of the second piston 423.

The second working chamber S5 is a space in the +Y direction for the second piston 423 in the space on the inside of the second guide part 414. That is, the second working chamber S5 is a space provided between the mechanism chamber S1 and the second pressure chamber S4 on the inside of the second guide part 414 and divided from the second pressure chamber S4 by the second piston 423. A space between the mechanism chamber S1 and the second working chamber S5 is sealed by the other of the two first sealing members 416.

The second guide part 414 includes a second partition wall 4141, a second discharge valve 4143, and a second outflow part 4144 that are the same as the first partition wall 4121, the first discharge valve 4123, and the first outflow part 4124 of the first guide part 412.

The second partition wall 4141 segments the second pressure chamber S4 into a second suction chamber, which is a space in the +Y direction, and a second high-pressure chamber, which is a space in the -Y direction. A through-hole 4142 piercing through the second partition wall 4141 in the +Y direction is provided in the second partition wall 4141. The second suction chamber and the second high-pressure chamber communicate via the through-hole 4142. The working fluid is supplied to the second suction chamber from the second working chamber S5 via a channel 4231 of the second piston 423.

The second discharge valve 4143 opens when the pressure in the second suction chamber is higher than the pressure in the second high-pressure chamber.

The second outflow part 4144 is provided in a portion on the second high-pressure chamber side in the second guide part 414. The second outflow part 4144 is coupled to the first pipe 241.

Another part of the working fluid flows into a space in the second guide part 414 and is supplied into the second suction chamber via the channel 4231 and a suction valve 4232 of the second piston 423 by reciprocation of the second piston 423. Thereafter, the working fluid in the gas phase flows into the second high-pressure chamber from the second suction chamber via the second discharge valve 4143 while being compressed by the second piston 423 and flows out to the first pipe 241 from the second outflow part 4144.

### Configuration of the Second Segmenting Part

The second segmenting part 415 is a segmenting part that is provided in a coupling portion of the housing part 411 and the second guide part 414 and segments the mechanism chamber S1 and the second working chamber S5. The second segmenting part 415 projects in the inner diameter direction from a portion on the second guide part 414 side in the housing part 411. The second segmenting part 415 includes a communication hole 4151 and a disposing part 4152.

The communication hole 4151 pierces through the second segmenting part 415 in the +Y direction. The rod 421 of the slide member 42 is inserted through the communication hole 4151 in the +Y direction. That is, the second working chamber S5 is connected to the mechanism chamber S1 via the communication hole 4151.

The disposing part 4152 is a portion where the other of the two first sealing members 416 is disposed in the second segmenting part 415.

### Configuration of the Slide Member

The slide member 42 is coupled to the coupling member 43, slides in the ±Y direction together with the coupling member 43, and changes the capacities of the first pressure chamber S2 and the second pressure chamber S4. The slide member 42 includes the rod 421, the first piston 422, and the second piston 423.

The rod 421 is a shaft member extending in the +Y direction. A center portion of the rod 421 in the +Y direction is disposed in the mechanism chamber S1. The rod 421 is coupled to the coupling member 43.

The first piston 422 is a piston provided at the end portion of the rod 421 in the +Y direction and disposed in the first guide part 412. The first piston 422 has an outer diameter larger than the outer diameter of the rod 421. When the rod 421 reciprocates in the +Y direction, the first piston 422 reciprocates in the +Y direction in the first guide part 412. When sliding in the +Y direction, the first piston 422 reduces the capacity of the first pressure chamber S2. Consequently, the first piston 422 compresses the working fluid in the gas phase flowing into the first pressure chamber S2. The working fluid in the gas phase is an example of the gas.

The second piston 423 is a piston provided at the end portion of the rod 421 in the -Y direction and disposed in the second guide part 414. The second piston 423 has an outer diameter larger than the outer diameter of the rod 421. When the rod 421 reciprocates in the +Y direction, the second piston 423 reciprocates in the +Y direction in the second guide part 414.

When sliding in the -Y direction, the second piston 423 reduces the capacity of the second pressure chamber S4. Consequently, the second piston 423 compresses the working fluid in the gas phase flowing into the second pressure chamber S4. As explained above, the working fluid in the gas phase is an example of the gas.

### Configuration of the Coupling Member

The coupling member 43 is disposed in the mechanism chamber S1. The coupling member 43 is coupled to the slide member 42, the first rotating member 44, and the second rotating member 46. The coupling member 43 moves in the ±Y direction according to rotation of the rotating members 44 and 46 and moves the slide member 42 in the ±Y direction. In other words, the coupling member 43 converts rotational motions of the rotating members 44 and 46 into linear motions in the ±Y direction of the slide member 42.

The coupling member 43 includes a first end portion 431 in the -X direction and a second end portion 432 in the +X direction.

The first end portion 431 is inserted into a spherical bearing 443 provided in the first rotating member 44.

The second end portion 432 is inserted into a spherical bearing 463 provided in the second rotating member 46.

When the first end portion 431 is inserted into the spherical bearing 443 and the second end portion 432 is inserted into the spherical bearing 463, the coupling member 43 is disposed in the +X direction.

### Configuration of the First Rotating Member

The first rotating member 44 is coupled to a first rotor 451 of the first motor 45 and the first end portion 431 of the coupling member 43. The first rotating member 44 rotates together with the first rotor 451 coaxially with the first rotor 451. That is, the first rotating member 44 is coupled to the first end portion 431, which is one end of the coupling member 43, and rotates centering on the rotation axis Rx1 extending in the +X direction. In other words, the first rotating member 44 is integrated with the first rotor 451 and rotates centering on the rotation axis Rx1 together with the first rotor 451. The rotation axis Rx1 is equivalent to the first rotation axis.

The first rotating member 44 includes a semicircular first weight 441, a hole 442, the spherical bearing 443, and a fitting part 444.

The first weight 441 is a counter weight for reducing vibration caused by reciprocation of the slide member 42 in the +Y direction. When the slide member 42 slides in the +Y direction most, that is, when the slide member 42 slides to the top dead center, the first weight 441 is disposed in the -Y direction with respect to the rotation axis Rx1. In other words, when the slide member 42 slides in the -Y direction most, that is, when the slide member 42 slides to the bottom dead center, the first weight 441 is disposed in the +Y direction with respect to the rotation axis Rx1.

The hole 442 pierces through the first rotating member 44 in the +X direction. The spherical bearing 443 is provided on the inside of the hole 442. The first end portion 431 is inserted into the inside of the spherical bearing 443.

The end portion in the +X direction in the first rotor 451 is inserted into and fit in the fitting part 444. Consequently, the first rotating member 44 rotates integrally with the first rotor 451.

### Configuration of the Second Rotating Member

The second rotating member 46 is coupled to a second rotor 471 of the second motor 47 and the second end portion 432 of the coupling member 43 and rotates coaxially with the second rotor 471 together with the second rotor 471. That is, the second rotating member 46 is coupled to the second end portion 432, which is the other end of the coupling member 43, and rotates, centering on the rotation axis Rx2 extending in the +X direction, in the opposite direction of a rotating direction of the first rotating member 44. In other words, the second rotating member 46 is integrated with the second rotor 471 and rotates centering on the rotation axis Rx2 together with the second rotor 471. The rotation axis Rx2 is equivalent to the second rotation axis. The rotation axis Rx2 is located on an extended line of the rotation axis Rx1. That is, the extended line of the rotation axis Rx1 and an extended line of the rotation axis Rx2 substantially coincide.

The second rotating member 46 includes a semicircular second weight 461, a hole 462, the spherical bearing 463, and a fitting part 464.

Like the first weight 441, the second weight 461 is a counter weight for reducing vibration caused by reciprocation of the slide member 42 in the +Y direction. The second weight 461 is disposed in the -Y direction with respect to the rotation axis Rx2 when the slide member 42 slides to the top dead center and is disposed in the +Y direction with respect to the rotation axis Rx2 when the slide member 42 slides to the bottom dead center.

The hole 462 pierces through the second rotating member 46 in the +X direction. The spherical bearing 463 is provided on the inside of the hole 462. The second end portion 432 is inserted into the inside of the spherical bearing 463.

The end portion in the -X direction in the second rotor 471 is inserted into and fit in the fitting part 464. Consequently, the second rotating member 46 rotates integrally with the second rotor 471.

Although not shown, when moving in the ±Y direction according to rotation of the rotating members 44 and 46 that rotate in opposite directions each other, the coupling member 43 is turned clockwise or counterclockwise when viewed from the +Y direction centering on an axis extending in the +Y direction. Specifically, when the coupling member 43 located at the bottom dead center is moved in the +Y direction according to the rotation of the rotating members 44 and 46, the coupling member 43 is turned in one direction of the clockwise direction and the counterclockwise direction when viewed from the +Y direction until the coupling member 43 reaches the half of a moving range in the +Y direction. When the coupling member 43 located in the top dead center is moved in the -Y direction according to the rotation of the rotating members 44 and 46, the coupling member 43 turns in the other direction of the clockwise direction and the counterclockwise direction when viewed from the +Y direction until the coupling member 43 reaches the half of a moving range in the -Y direction. The coupling member 43 turns in one direction of the clockwise direction and the counterclockwise direction when viewed from the +Y direction until the coupling member 43 reaches the bottom dead center from a position of the half of the moving range in the -Y direction. In this way, when reciprocating in the +Y direction, the coupling member 43 swings clockwise or counterclockwise when viewed from the +Y direction centering on the axis extending in the +Y direction.

### Configuration of the First Motor

The first motor 45 is coupled to the first rotating member 44. The first motor 45 rotates the first rotating member 44 and moves the coupling member 43 and the slide member 42 in the ±Y direction. The first motor 45 includes the first rotor 451, a first stator 452, and a first case 453.

### Configuration of the First Rotor

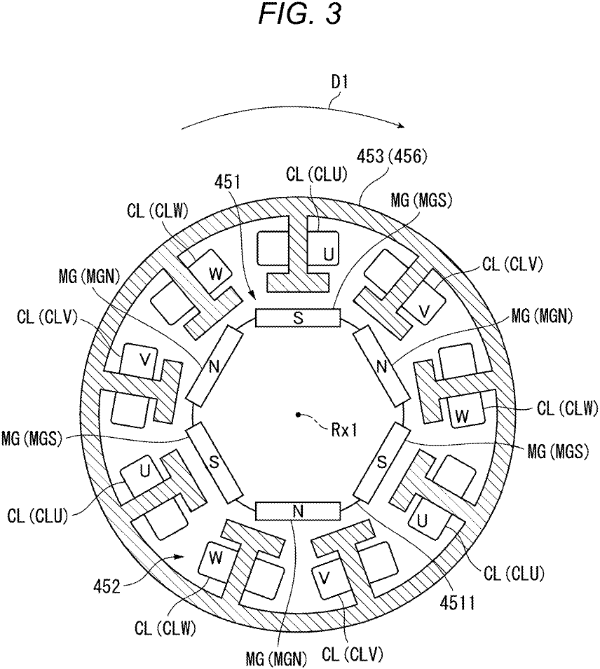

FIG. 3 is a schematic diagram in which a cross section of the first motor 45 taken along an imaginary surface orthogonal to the +X direction is viewed from the -X direction.

The first rotor 451 extends in the +X direction. The first rotor 451 is coupled to the first rotating member 44 and is rotated by the first stator 452 centering on the rotation axis Rx1. The first rotor 451 includes, as shown in FIG. 3, a shaft 4511 and a plurality of magnets MG.

The shaft 4511 is a shaft member configuring a main body of the first rotor 451. The end portion in the +X direction in the shaft 4511 is inserted into the fitting part 444 of the first rotating member 44.

One of the second sealing members 417 is an oil seal that seals a space between the inner wall of the mechanism chamber S1 and the shaft 4511. The second sealing members 417 restrict the lubricant encapsulated in the mechanism chamber S1 from moving to the outside of the mechanism chamber S1.

The plurality of magnets MG are disposed at equal intervals in a circumferential direction D1 of the shaft 4511 centered on the rotation axis Rx1. The plurality of magnets MG include first magnets MGS and second magnets MGN. The first rotor 451 includes a plurality of sets of the first magnets MGS and the second magnets MGN. In this embodiment, the first rotor 451 includes three sets of the first magnets MGS and the second magnets MGN. That is, the first motor 45 is a six-pole motor.

The first magnets MGS and the second magnets MGN are disposed in positions on opposite sides each other across the rotation axis Rx1 in the shaft 4511. The first magnets MGS and the second magnets MGN are disposed alternately and at equal intervals in the circumferential direction D1. Magnetic poles on surfaces facing the outer side of the first rotor 451 in the first magnets MGS and magnetic poles on surfaces facing the outer side of the first rotor 451 in the second magnets MGN are different from each other. Specifically, the magnetic poles on the surfaces facing the outer side of the first rotor 451 in the first magnets MGS are S poles and the magnetic poles on the surfaces facing the outer side of the first rotor 451 in the second magnets MGN are N poles.

### Configuration of the First Stator

The first stator 452 is a rotator that rotates the first rotor 451. The first stator 452 is disposed on the outer side of the first rotor 451 when viewed along the rotation axis Rx1 and rotates the first rotor 451.

The first stator 452 includes a plurality of coils CL provided at substantially equal intervals on the inside of the first case 453. The plurality of coils CL include first phase coils CLU, second phase coils CLV, and third phase coils CLW. The first stator 452 includes three sets of the first phase coils CLU, the second phase coils CLV, and the third phase coils CLW. That is, the first motor 45 is a three-phase nine-slot motor. The first stator 452 includes three first phase coils CLU, three second phase coils CLV, and three third phase coils CLW. The first case 453 is a stator in which the coils CL are provided.

The three first phase coils CLU are provided at substantially equal intervals in the circumferential direction D1. That is, the three first phase coils CLU are disposed at substantially 120° intervals in the circumferential direction centered on the rotation axis Rx1. Each of the three second phase coils CLV and the three third phase coils CLW are also provided at substantially equal intervals in the circumferential direction D1 like the three first phase coils CLU.

The first phase coils CLU, the second phase coils CLV, and the third phase coils CLW are disposed at substantially equal intervals in order in the circumferential direction D1. Specifically, the second phase coils CLV are disposed in positions shifted approximately 40° in the circumferential direction D1 from the first phase coils CLU. The third phase coils CLW are disposed in positions shifted approximately 40° in the circumferential direction D1 from the second phase coils CLV. The first phase coils CLU are disposed in positions shifted approximately 40° in the circumferential direction D1 from the third phase coils CLW.

### Schematic Configuration of the First Case

The first case 453 is a cylindrical member that houses a part of the first rotor 451 and the first stator 452. Specifically, the first case 453 supports the first rotor 451 rotatably centering on the rotation axis Rx1 and supports the plurality of coils CL of the first stator 452.

Such a configuration of the first case 453 is explained in detail below.

### Configuration of the Second Motor

As shown in FIG. 2, the second motor 47 is provided in the +X direction on the opposite side of the first motor 45 with respect to the slide member 42. The second motor 47 is coupled to the second rotating member 46. The second motor 47 rotates the second rotating member 46 in the opposite direction of the first rotating member 44 and moves the coupling member 43 and the slide member 42 in the ±Y direction. The second motor 47 includes the second rotor 471, a second stator 472, and a second case 473.

The second rotor 471 is coupled to the second rotating member 46 and rotated by the second stator 472 centering on the rotation axis Rx2. The second rotor 471 includes the same configuration as the configuration of the first rotor 451. The other one of the second sealing members 417 is an oil seal that seals a space between the inner wall of the mechanism chamber S1 and the shaft 4711 of the second rotor 471 and restricts the lubricant encapsulated in the mechanism chamber S1 from moving to the outside of the mechanism chamber S1.

The second stator 472 is disposed on an outer side of the second rotor 471 when viewed along the rotation axis Rx2 and rotates the second rotor 471. The second stator 472 includes the same configuration as the configuration of the first stator 452. That is, the second stator 472 includes three sets of the first phase coils CLU, the second phase coils CLV, and the third phase coils CLW.

The second case 473 includes the same configuration as the configuration of the first case 453.

In this way, like the first motor 45, the second motor 47 is a three-phase nine-slot motor including six poles.

### Reduction of Vibration

In a positive displacement machine, vibration occurs when a motor rotates. In contrast, in a positive displacement machine including two motors disposed across a slider, the two motors rotate rotating members corresponding to the two motors in opposite directions each other, whereby vibration that occurs in one motor is offset by vibration that occurs in the other motor. Consequently, vibration that occurs in the positive displacement machine is reduced. However, there has been a demand for a positive displacement machine in which vibration is further reduced.

In response to the demand, as a result of researches, the inventor according to the present disclosure found that it is possible to further reduce vibration of the positive displacement machine by aligning rotation phases of the two motors. The inventor according to the present disclosure examined the following two methods as a method of aligning rotation phases of motors and reducing vibration in a positive displacement machine.

A first method is a method of using a first driving circuit that controls one motor of two motors, a second driving circuit that controls the other motor, and two encoders that detect rotation states of rotors included in the motors. The driving circuits monitor, based on detection results by the encoders, a rotation phase of a rotor included in one motor and a rotation phase of a rotor included in the other motor and controls driving of the motors at high speed such that the rotation phase of one motor and the rotation phase of the other motor are the same. Specifically, in the first method, the first driving circuit and the second driving circuit finely control electric currents for energizing the motors and align the rotation phases of the motors.

In this way, it is possible to maintain equal torque by the two driving circuits controlling the driving of the motors. Besides, vibration in a more appropriate antiphase can be caused in the other motor with respect to vibration that occurs in one motor. Therefore, it is possible to further reduce vibration that occurs in the positive displacement machine.

However, in the first method, an encoder to be adopted needs to have sufficiently high resolution. Besides, since the two driving circuits are provided, cost of the positive displacement machine tends to increase.

In order to align a rotation phase of one rotor and a rotation phase of the other rotor, it is necessary to reduce a current value of an electric current for energizing one motor and increase a current value of an electric current for energizing the other motor. However, it is difficult to finely control the current values.

Accordingly, in the first method, cost increases. Besides, it is difficult to align the rotation phases of the rotors and it is difficult to achieve a further vibration reduction.

A second method is a method of driving two motors like one motor in which rotors of the two motors are coupled and coils of stators of the two motors are coupled. Specifically, the second method is a method of simultaneously driving the two motors in which angle phases of the rotors with respect to the stators are aligned. Specifically, the second method is a method of adjusting an angle of the stators with respect to the rotors in a state in which the coils of the same phase are excited in the motors to thereby drive the two motors in which the angle phases of the stators with respect to the rotors are aligned.

With such a second method, when the two motors are driven, it is possible to align a rotation phase of one rotor and a rotation phase of the other rotor. The two motors are provided in positions across a housing and rotating directions of the two rotors are opposite directions each other. Accordingly, vibration having a phase inverted with respect to vibration that occurs in one motor can be caused to occur in the other motor. Therefore, the vibration that occurs in one motor can be effectively offset by the vibration that occurs in the other motor. It is possible to reduce vibration that occurs in the positive displacement machine.

### Method of Attaching the Motors to the Housing

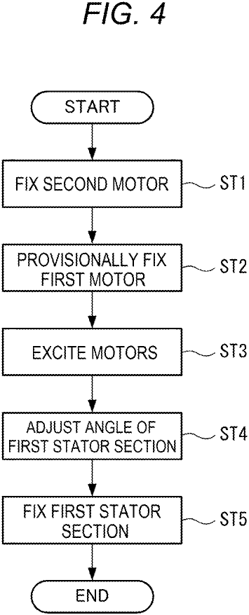

FIG. 4 is a flowchart showing a method of attaching the two motors to the housing.

The inventor according to the present disclosure devised a motor attaching method explained below in order to implement the second method explained above. A motor attaching method according to this embodiment is explained below with reference to the configuration of the positive displacement machine 4 explained above and FIG. 4.

In the following explanation, it is assumed that the slide member 42, the coupling member 43, the first rotating member 44, and the second rotating member 46 provided in the housing 41 are already coupled.

The motor attaching method explained below is a method of adjusting an angle phase of the first stator 452. However, the same applies when an angle phase of the second stator 472 is adjusted.

In the motor attaching method according to this embodiment, as shown in FIG. 4, first, the second motor 47 is fixed to the housing 41 (step ST1). At this time, the end portion in the -X direction in the second rotor 471 is fit in the fitting part 464 of the second rotating member 46 and the second case 473 is fixed to the housing 41.

Subsequently, the first motor 45 is provisionally fixed to the housing 41 (step ST2). Specifically, in step ST2, a first motor case 454 explained below is fixed to the housing 41 while the end portion in the +X direction in the first rotor 451 of the first motor 45 being fit in the fitting part 444 of the first rotating member 44. However, a stator holder 456 explained below is not fixed to the first motor case 454 to enable the first stator 452 to rotate centering on the rotation axis Rx1 with respect to the first rotor 451.

Thereafter, the first motor 45 and the second motor 47 are simultaneously excited (step ST3). Specifically, in step ST3, the coils CL in the same phase are energized with an electric current in the first stator 452 and the second stator 472.

For example, when the first phase coil CLU among the plurality of coils CL included in the second stator 472 is excited, the first phase coil CLU among the plurality of coils CL included in the first stator 452 is excited. At this time, in each of the first stator 452 and the second stator 472, all the first phase coils CLU are excited.

When the second motor 47 is excited, the second rotor 471 and the second stator 472 stop in positions where the second rotor 471 and the second stator 472 attract each other. The position of the second rotor 471 is fixed. For example, when the first phase coil CLU is energized, since the first phase coil CLU changes to an N pole, the second rotor 471 is fixed in a position where the first phase coil CLU and the first magnet MGS are opposed to each other.

The first rotor 451 is coupled to the second rotor 471 via the first rotating member 44, the coupling member 43, and the second rotating member 46. Therefore, the first rotor 451 is also fixed according to the fixing of the second rotor 471.

Subsequently, the first stator 452 is rotated centering on the rotation axis Rx1 and an angle of the first stator 452 centered on the rotation axis Rx1 is adjusted (step ST4). That is, in step ST4, the angle of the first stator 452 is adjusted such that an angle phase of the first stator 452 with respect to the first rotor 451 and an angle phase of the second stator 472 with respect to the second rotor 471 are aligned. Specifically, the first stator 452 is rotated centering on the rotation axis Rx1 and the position of the first stator 452 is adjusted such that a crossing angle of an imaginary line connecting the excited coil CL and the rotation axis and an imaginary line connecting, of the first magnet MGS and the second magnet MGN, the magnet MG attracting the excited coil CL and the rotation axis is the same in the first motor 45 and the second motor 47.

For example, when the excited coil CL is the first phase coil CLU, in step ST4, the position of the first stator 452 is adjusted such that a crossing angle of a first imaginary line connecting the first phase coil CLU in the second motor 47 and the rotation axis Rx2 and a second imaginary line connecting the first magnet MGS attracting the first phase coil CLU and the rotation axis Rx2 is the same as a crossing angle of a first imaginary line connecting the first phase coil CLU in the first motor 45 and the rotation axis Rx1 and a second imaginary line connecting the first magnet MGS attracting the first phase coil CLU and the rotation axis Rx1. Consequently, the rotation phase of the first motor 45 and the rotation phase of the second motor 47 are aligned.

When sliding resistance is large, the first stator 452 is stopped at a point where an excitation force and a frictional force are balanced. Therefore, a stop position of the first stator 452 at the time when the first stator 452 is rotated clockwise centering on the rotation axis Rx1 and a stop position of the first stator 452 at the time when the first stator 452 is rotated counterclockwise centering on the rotation axis Rx1 are sometimes different. In this case, the excitation may be performed in a state in which the first stator 452 is disposed in a position sufficiently offset from an assumed position. An intermediate position of the stop position of the first stator 452 in the clockwise direction and the stop position of the first stator 452 in the counterclockwise direction may be set as a position of the first stator 452 at the time when the rotation phase of the first motor 45 and the rotation phase of the second motor 47 are aligned.

When it is desired to more accurately detect the position of the first stator 452, in a state in which the motors are excited, the first stator 452 may be rotated while rotation torque of the first stator 452 being measured by a torque sensor and a position where the rotation torque is the maximum may be set as the position of the first stator 452 at the time when the rotation phases of the motors 45 and 47 are aligned. In this case, by causing the first stator 452 to perform an equiangular velocity motion, variation of a stop position due to an inertial moment of the first stator 452 can be eliminated.

If the first stator 452 is rotated at sufficiently low speed in a period in which seizure of the motors does not occur, the motor may be rotated only in one direction of the clockwise direction and the counterclockwise direction. In order to reduce a tact time of step ST4, an intermediate position of a peak at the clockwise time and a peak at the counterclockwise time may be set as the position of the first stator 452 at the time when the rotation phases of the motors 45 and 47 are aligned.

After the rotation phases of the motors 45 and 47 are aligned in step ST4, the first stator 452 is fixed (step ST5). Specifically, in step ST5, the stator holder 456 of the first case 453 is fixed to the first motor case 454 fixed to the housing 41. Consequently, the rotation phases of the motors 45 and 47 can be maintained in an aligned state.

### Detailed Configuration of the First Case

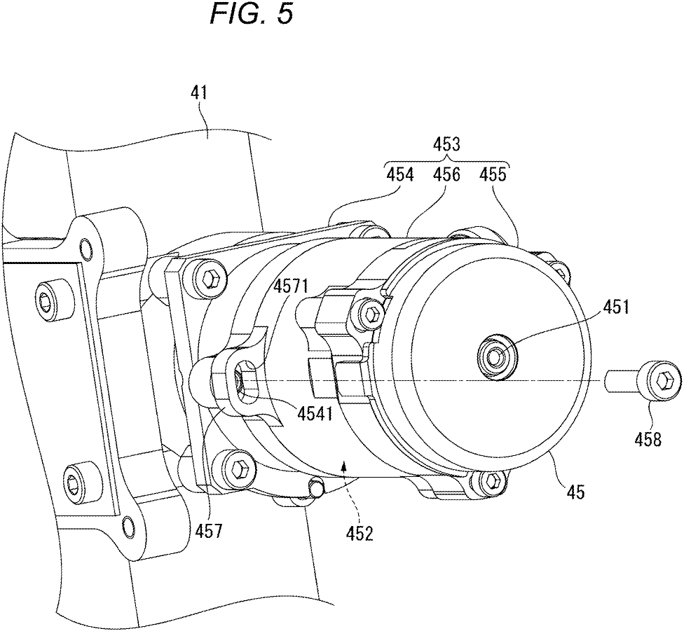

FIG. 5 is a perspective view showing the first motor 45 attached to the housing 41.

For example, in order to make it possible to implement the motor attaching method explained above, the first case 453 includes, as shown in FIG. 5, the first motor case 454, a second motor case 455, and the stator holder 456.

The first motor case 454 and the second motor case 455 are formed in a substantially cylindrical shape. The motor cases 454 and 455 support the first rotor 451 disposed on the inside to be capable of rotating centering on the rotation axis Rx1. The first motor case 454 is fixed to a surface facing the -X direction in the housing 41. The second motor case 455 is coupled to the stator holder 456.

The stator holder 456 is disposed between the first motor case 454 and the second motor case 455 and houses the plurality of coils CL included in the first stator 452. That is, the stator holder 456 functions as a stator for the plurality of coils CL.

The stator holder 456 is capable of rotating centering on the rotation axis Rx1 with respect to the first rotor 451 supported by the motor cases 454 and 455. The stator holder 456 includes first adjusting mechanisms 457.

### Configuration of the First Adjusting Mechanisms

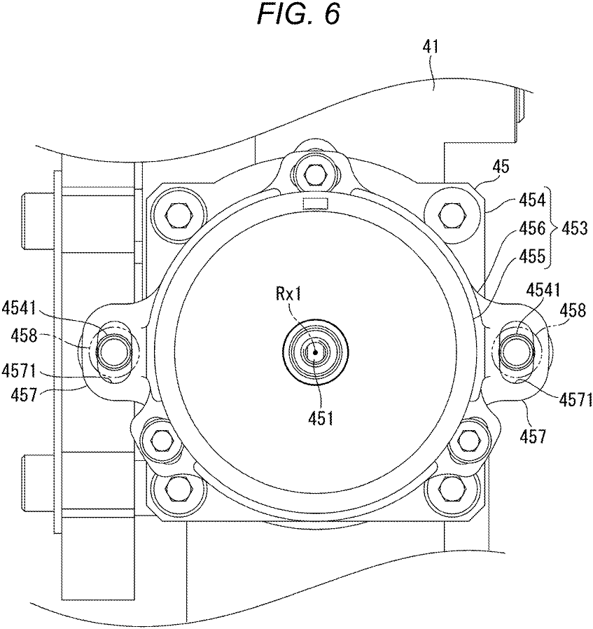

FIG. 6 is a side view showing the first motor 45 viewed from the -X direction.

The first adjusting mechanisms 457 are portions that make it possible to adjust an angle of the stator holder 456 centered on the rotation axis Rx1. In other words, the first adjusting mechanisms 457 are portions centered on the rotation axis Rx1 and capable of adjusting an angle of the first stator 452 with respect to the first rotor 451. That is, the first motor 45 includes the first adjusting mechanisms 457 configured to adjust the angle of the first stator 452 with respect to the first rotor 451, the angle being centered on the rotation axis Rx1.

Two first adjusting mechanisms 457 are provided across the rotation axis Rx1. The first adjusting mechanisms 457 include long holes 4571 formed in an arcuate shape centered on the rotation axis Rx1. Fixing members 458 are inserted through the long holes 4571. In this embodiment, the fixing members 458 are screws. The fixing members 458 are fixed to, via washers (not shown), fixing parts 4541, which are screw holes provided in the first motor case 454 to correspond to the first adjusting mechanisms 457, after being inserted through the long holes 4571. Consequently, the stator holder 456 is fixed to the first motor case 454 and fixed to the housing 41.

A dimension of the long holes 4571 in the radial direction centered on the rotation axis Rx1 is smaller than the outer diameter of heads of the fixing members 458, which are the screws. However, a dimension of the long holes 4571 in the circumferential direction D1 is larger than shafts of the fixing members 458. Consequently, it is possible to rotate the stator holder 456 in the circumferential direction D1. It is possible to adjust the angle of the first stator 452 with respect to the first rotor 451. The angle of the first stator 452 can be adjusted by such first adjusting mechanisms 457 such that a crossing angle of an imaginary line connecting the excited coil CL and the rotation axis and an imaginary line connecting, of the first magnet MGS and the second magnet MGN, the magnet MG attracting the excited coil CL and the rotation axis is the same in the first motor 45 and the second motor 47. Consequently, a crossing angle of a first imaginary line connecting one coil CL among the first phase coil CLU, the second phase coil CLV, and the third phase coil CLW and the rotation axis and a second imaginary line connecting one magnet MG of the first magnet MGS and the second magnet MGN and the rotation axis is the same in the first motor 45 and the second motor 47.

In this state, the fixing members 458 are fixed to the fixing parts 4541, whereby the first stator 452, the angle of which with respect to the first rotor 451 is adjusted, is fixed. That is, the first motor 45 and the positive displacement machine 4 include the fixing members 458 that fix the first stator 452, the angle of which is adjusted by the first adjusting mechanisms 457.

In order to implement step ST4, a motor in which a stator is rotatable with respect to a rotor may be one motor of the first motor 45 and the second motor 47. In the example explained above, the stator rotatable with respect to the rotor may be only the first stator 452.

On the other hand, in the positive displacement machine 4 according to this embodiment, as shown in FIG. 2, like the first case 453, the second case 473 includes a first motor case 474, a second motor case 475, and a stator holder 476. Further, the second case 473 includes second adjusting mechanisms (not shown) that are the same as the first adjusting mechanisms 457. That is, the second motor 47 includes the second adjusting mechanisms configured to adjust an angle of the second stator 472 with respect to the second rotor 471, the angle being centered on the rotation axis Rx2. Consequently, it is possible to expand an adjustable range of the rotation phases of the motors 45 and 47. Besides, the first motor 45 and the second motor 47 can be configured as motors including the same configuration. Therefore, it is possible to reduce cost compared with when two motors different in configurations from each other are adopted.

### Another Configuration of the Positive Displacement Machine

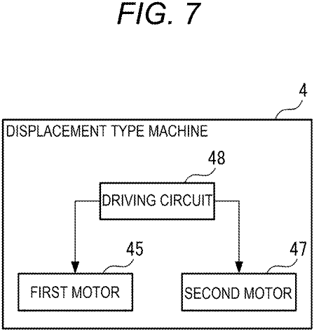

FIG. 7 is a block diagram showing another configuration of the positive displacement machine 4.

The positive displacement machine 4 further includes one driving circuit 48 as shown in FIG. 7.

The one driving circuit 48 controls both the first motor 45 and the second motor 47. Specifically, the driving circuit 48 is electrically coupled to both the first motor 45 and the second motor 47 and outputs the same driving signal to the first motor 45 and the second motor 47. That is, the driving circuit 48 drives both the first motor 45 and the second motor 47 as one motor disposed in series. In other words, the driving circuit 48 can drive both the first motor 45 and the second motor 47 as one motor having the same rotation phase.

### Effects of the Embodiment

The electronic equipment 1 according to this embodiment explained above achieves the following effects.

The electronic equipment 1 includes the cooling apparatus 2.

The cooling apparatus 2 includes the compressor 3, the condenser 21, the expander 22, and the evaporator 23. The condenser 21 condenses working fluid in a gas phase compressed by the compressor 3 into the working fluid in a liquid phase. The expander 22 decompresses the working fluid in the liquid phase condensed by the condenser 21 and changes a state of the working fluid to a state in which the liquid phase and the gas phase are mixed. The evaporator 23 is coupled to the cooling target CT to be capable of transferring heat. The evaporator 23 changes the working fluid flowing from the expander 22 to the working fluid in the gas phase with the heat transferred from the cooling target CT and discharges the changed working fluid in the gas phase to the compressor 3.

The compressor 3 includes the positive displacement machine 4. The first piston 422 of the positive displacement machine 4 compresses gas flowing into the first pressure chamber S2 and the second piston 423 compresses gas flowing into the second pressure chamber S4.

The positive displacement machine 4 includes the housing 41, the slide member 42, the coupling member 43, the first rotating member 44, the first motor 45, the second rotating member 46, and the second motor 47.

The housing 41 includes the tubular first guide part 412 in which the first pressure chamber S2 is provided and the tubular second guide part 414 in which the second pressure chamber S4 is provided.

The slide member 42 includes the first piston 422 disposed in the first guide part 412 and the second piston 423 disposed in the second guide part 414 and slides in the +Y direction. The +Y direction is equivalent to the first direction.

The coupling member 43 is coupled to the slide member 42 and extends in the +X direction crossing the +Y direction. The +X direction is equivalent to the second direction.

The first rotating member 44 is coupled to the first end portion 431 of the coupling member 43 and rotates centering on the rotation axis Rx1 extending in the +X direction. The first end portion 431 is equivalent to one end of the coupling member 43. The rotation axis Rx1 is equivalent to the first rotation axis.

The second rotating member 46 is coupled to the second end portion 432 of the coupling member 43 and rotates, centering on the rotation axis Rx2 extending along the +X direction, in the opposite direction of the rotating direction of the first rotating member 44. The second end portion 432 is equivalent to the other end of the coupling member 43. The rotation axis Rx2 is equivalent to the second rotation axis.

The first motor 45 includes the first rotor 451 and the the first stator 452. The first rotor 451 is coupled to the first rotating member 44 and rotates centering on the rotation axis Rx1. The first stator 452 is disposed on the outer side of the first rotor 451 when viewed along the rotation axis Rx1.

The second motor 47 includes the second rotor 471 and the second stator 472. The second rotor 471 is coupled to the second rotating member 46 and rotates centering on the rotation axis Rx2. The second stator 472 is disposed on the outer side of the second rotor 471 when viewed along the rotation axis Rx2.

The first motor 45 includes the first adjusting mechanisms 457 configured to adjust an angle of the first stator 452 with respect to the first rotor 451, the angle being centered on the rotation axis Rx1. The same applies to the second motor 47.

With such a configuration, by adjusting an angle of the first stator 452 included in the first motor 45 using the first adjusting mechanisms 457, it is possible to align an angle phase of the first stator 452 with respect to the first rotor 451 in the first motor 45 and an angle phase of the second stator 472 with respect to the second rotor 471 in the second motor 47. Therefore, the first motor 45 and the second motor 47 can be rotated in opposite directions each other as motors having the same rotation characteristic. Consequently, it is possible to make it easy to offset vibration caused by one motor of the first motor 45 and the second motor 47 being driven with vibration caused by the other motor being driven. Therefore, it is possible to reduce vibration that occurs at the driving time of the positive displacement machine 4. Consequently, it is possible to configure the compressor 3, the cooling apparatus 2, and the electronic equipment 1 capable of reducing vibration at the operation time. Besides, since the rotation phases of the motors 45 and 47 are aligned, it is possible to improve efficiency of the motors 45 and 47.

The positive displacement machine 4 further includes one driving circuit 48 that controls both the first motor 45 and the second motor 47.

With such a configuration, even when the positive displacement machine 4 includes the one driving circuit 48, it is possible to drive both the first motor 45 and the second motor 47 such that vibration that occurs in the positive displacement machine 4 is reduced. Therefore, it is possible to simplify the configuration of the positive displacement machine 4 compared with when driving circuits are provided to correspond to each of the first motor 45 and the second motor 47.

In the positive displacement machine 4, the first motor 45 includes the fixing members 458 that fix the first stator 452, the angle of which is adjusted by the first adjusting mechanisms 457. The same applies to the second motor 47.

With such a configuration, it is possible to prevent the stators 452 and 472, the angles of which are adjusted, from suddenly rotating.

In the positive displacement machine 4, the fixing members 458 are screws. The first adjusting mechanisms 457 include the long holes 4571 having an arcuate shape centered on the rotation axis Rx1, the fixing members 458 being inserted into the long holes 4571. The same applies to the second adjusting mechanisms of the second motor 47.

With such a configuration, even after the fixing members 458, which are the screws, are provisionally fixed in a state in which the fixing members 458 are inserted into the long holes 4571, the first stator 452 can be rotated centering on the rotation axis Rx1. The same applies to the second stator 472. Therefore, it is possible to make it easy to implement operation for adjusting the angles of the stators 452 and 472.

In the positive displacement machine 4, the second motor 47 includes the second adjusting mechanisms configured to adjust an angle of the second stator 472 with respect to the second rotor 471, the angle being centered on the rotation axis Rx2.

With such a configuration, an angle of a stator with respect to a rotor can be adjusted in each of the first motor 45 and the second motor 47. Consequently, it is possible to adjust angle phases of the motors 45 and 47 more in detail. Therefore, it is possible to increase adjustment flexibility and further reduce vibration that occurs at the driving time of the positive displacement machine 4.

In the positive displacement machine 4, the first rotor 451 includes the shaft 4511, the first magnets MGS, and the second magnets MGN. The shaft 4511 is capable of rotating centering on the rotation axis Rx1. The first magnets MGS and the second magnets MGN are disposed in positions on opposite sides each other across the rotation axis Rx1 in the shaft 4511. Magnetic poles on surfaces facing the outer side are different from each other in the first magnets MGS and the second magnets MGN. The first stator 452 includes the first phase coils CLU, the second phase coils CLV, and the third phase coils CLW disposed at equal intervals from one another in the circumferential direction D1 centered on the rotation axis Rx1. A crossing angle of a first imaginary line connecting the first phase coil CLU and the rotation axis and a second imaginary line connecting one magnet of the first magnet MGS and the second magnet MGN and the rotation axis is the same in the first motor 45 and the second motor 47.

With such a configuration, an angle phase of the first stator 452 in the first motor 45 and an angle phase of the second stator 472 in the second motor 47 can be aligned. Therefore, vibrations that occur in the motors 45 and 47 can be offset each other. It is possible to reduce vibration that occurs at the driving time of the positive displacement machine 4.

### Modifications of the Embodiment

The present disclosure is not limited to the embodiment explained above. Modifications, improvements, and the like in a range in which the object of the present disclosure can be achieved are included in the present disclosure.

In the embodiment, the positive displacement machine 4 includes the one driving circuit 48 that controls both the first motor 45 and the second motor 47. However, not only this, but the positive displacement machine 4 may include a first driving circuit that controls the first motor 45 and a second driving circuit that controls the second motor 47 and the first driving circuit and the second driving circuit may drive the first motor 45 and the second motor 47 in synchronization.

In the embodiment, the first motor 45 includes the first adjusting mechanisms 457 and the second motor 47 includes the second adjusting mechanisms that are the same as the first adjusting mechanisms 457. However, not only this, but one motor of the first motor 45 and the second motor 47 may include adjusting mechanisms and the other motor may not include adjusting mechanisms.

In the embodiment, the first motor 45 includes the fixing members 458 that fix the first stator 452, the angle of which is adjusted by the first adjusting mechanisms 457. That is, the positive displacement machine 4 includes the fixing members 458 that fix the first stator 452, the angle of which is adjusted. However, not only this, but the fixing members 458 may be absent if the adjusted angle of the first stator 452 can be maintained by the first adjusting mechanisms 457. The fixing members 458 are the screws. However, the first motor 45 may include another component if the first stator 452 can be fixed to the housing 41 or the first motor case 454.

In the embodiment, the first adjusting mechanisms 457 included in the first motor 45 include the long holes 4571 having the arcuate shape centered on the rotation axis Rx1, the fixing members 458 being inserted into the long holes 4571. However, not only this, but the first adjusting mechanisms 457 may include another component if the first stator 452 can be rotated relatively to the first rotor 451 centering on the rotation axis Rx1. For example, the first adjusting mechanisms 457 may include, instead of the long holes 4571, holes (clearance holes) having an inner diameter larger than the outer diameter of the shafts of the fixing members 458, which are the screws.

In the embodiment, the fixing members 458 are attached to the fixing parts 4541 of the first motor case 454 fixed to the housing 41 and the first adjusting mechanisms 457 include the long holes 4571 through which the shafts of the fixing members 458 are inserted. However, not only this, but the housing 41 or the first motor case 454 may include, instead of the fixing members 458, shafts inserted into the long holes 4571. In this case, the fixing members 458 may be fastened to the shafts inserted into the long holes 4571 or may be attached to other portions of the housing 41 and the first motor 45. The same applies to the second adjusting mechanism.

In the embodiment, the first adjusting mechanisms 457 include the long holes 4571 through which the fixing members 458 fixed to the fixing parts 4541 are inserted. However, not only this, but the first adjusting mechanisms 457 may include shafts projecting toward the housing 41 or the first motor case 454. The housing 41 or the first motor case 454 may include holes, recesses, or grooves into which the shafts are inserted. In this case, the fixing members 458 may be attached to anywhere if the stator holder 456 can be fixed to the housing 41 or the first motor case 454. The same applies to the second adjusting mechanism.

In the embodiment, each of the first motor 45 and the second motor 47 is the six-pole three-phase nine-slot motor. That is, the first motor 45 includes the first rotor 451 including the three sets of the first magnets MGS and the second magnets MGN and the first stator 452 including the three sets of the first phase coils CLU, the second phase coils CLV, and the third phase coils CLW. The second motor 47 includes the second rotor 471 that is the same as the first rotor 451 and the second stator 472 that are the same as the first stator 452. However, not only this, but the first rotor 451 only has to include at least one set of the first magnet MGS and the second magnet MGN provided in the position of the shaft 4511 on opposite sides across the rotation axis Rx1. The first stator 452 only has to include at least one set of the first phase coil CLU, the second phase coil CLV, and the third phase coil CLW disposed at equal intervals from one another in the circumferential direction centered on the rotation axis. The same applies to the second rotor 471 and the second stator 472.

Further, the first stator 452 may include at least one set of the first phase coil CLU and the second phase coil CLV disposed at an equal interval from each other in the circumferential direction centered on the rotation axis Rx1. The same applies to the second stator 472. That is, a motor used in the positive displacement machine 4 may be a two-phase motor.

In the embodiment, the stator holder 456 in which the plurality of coils CL configuring the first stator 452 are provided is capable of rotating centering on the rotation axis Rx1 with respect to the first motor case 454 that supports the first rotor 451 to be rotatable centering on the rotation axis Rx1. The stator holder 456 is fixed to, by the fixing members 458, the first motor case 454 fixed to the housing 41. However, not only this, but the first stator 452 may be directly fixed to the housing 41. The first stator 452 may be integrated with the first motor case 454. That is, the first motor 45 may include the first case 453 in which the first motor case 454, the second motor case 455, and the stator holder 456 are integrated. The same applies to the second motor 47.

In the embodiment, the slide member 42 includes the first piston 422 provided at the end portion in the +Y direction in the rod 421 and the second piston 423 provided at the end portion in the -Y direction in the rod 421. However, not only this, but the slide member 42 may include one piston. For example, when the slide member 42 does not include the second piston 423, the positive displacement machine 4 may not include the second guide part 414, the second pressure chamber S4, and the second working chamber S5.

In the embodiment, the extended line of the rotation axis Rx1, which is the first rotation axis, and the extended line of the rotation axis Rx2, which is the second rotation axis, coincide. That is, the rotation axes Rx1 and Rx2 are rotation axes coinciding with each other. However, not only this, but the rotation axis Rx1 and the rotation axis Rx2 do not always have to coincide if the coupling member 43 to which the rotating members 44 and 46 are coupled is capable of moving in the +Y direction.

In the embodiment, the positive displacement machine 4 configures the compressor 3. However, the present disclosure may be applied to a positive displacement machine configuring a generator. That is, the positive displacement machine of the present disclosure is not limited to the positive displacement machine configuring the compressor that compresses gas.

In the embodiment, the compressor 3 compresses the working fluid that changes in phase between the liquid phase and the gas phase. However, gas compressed by the compressor of the present disclosure is not limited to the working fluid functioning as coolant. The compressor 3 configures the cooling apparatus 2. However, not only this, but the compressor of the present disclosure may configure another device or may be used alone.

### Summary of the Present Disclosure

A summary of the present disclosure is noted below.

[1] A positive displacement machine according to a first aspect of the present disclosure includes: a housing including a tubular guide part in which a pressure chamber is provided; a slide member including a piston disposed in the guide part, the slide member sliding in a first direction; a coupling member coupled to the slide member and extending in a second direction crossing the first direction; a first rotating member coupled to one end portion of the coupling member and configured to rotate centering on a first rotation axis extending in the second direction; a second rotating member coupled to another end of the coupling member and configured to rotate, centering on a second rotation axis extending along the second direction, in an opposite direction of a rotating direction of the first rotating member; a first motor including a first rotor coupled to the first rotating member and configured to rotate centering on the first rotation axis and a first stator disposed on an outer side of the first rotor when viewed along the first rotation axis; and a second motor including a second rotor coupled to the second rotating member and configured to rotate centering on the second rotation axis and a second stator disposed on an outer side of the second rotor when viewed along the second rotation axis. The first motor includes a first adjusting mechanism configured to adjust an angle of the first stator with respect to the first rotor, the angle being centered on the first rotation axis.

With such a configuration, by adjusting the angle of the first stator included in the first motor using the first adjusting mechanism, it is possible to align an angle phase of the first stator with respect to the first rotor in the first motor and an angle phase of the second stator with respect to the second rotor in the second motor. Therefore, as motors having the same rotation characteristic, the first motor and the second motor can be rotated in opposite directions each other. Consequently, it is possible to make it easy to offset vibration caused by one motor of the first motor and the second motor being driven with vibration caused by the other motor being driven. Therefore, it is possible to reduce vibration that occurs at a driving time of the positive displacement machine. Besides, since rotation phases of the motors are aligned, it is possible to improve efficiency of the motors.

[2] In the positive displacement machine described in [1], the positive displacement machine may further include one driving circuit configured to control both the first motor and the second motor.

With such a configuration, even when the positive displacement machine includes the one driving circuit, it is possible to drive the first motor and the second motor such that vibration that occurs in the positive displacement machine is reduced. Therefore, it is possible to simplify the configuration of the positive displacement machine compared with when driving circuits are provided to correspond to each of the first motor and the second motor.

[3] In the positive displacement machine described in [1] or [2], the positive displacement machine may further include a fixing member configured to fix the first stator, the angle of which is adjusted by the first adjusting mechanism.

With such a configuration, it is possible to prevent a stator, the angle of which is adjusted, from suddenly being displaced.

[4] In the positive displacement machine described in [3], the fixing member may be a screw, and the first adjusting mechanism may include a long hole having an arcuate shape centered on the first rotation axis, the fixing member being inserted into the long hole.

With such a configuration, even after the fixing member, which is the screw, is provisionally fixed in a state in which the fixing member is inserted into the long hole, it is possible to rotate the stators centering on the rotation axes. Therefore, it is possible to make it easy to implement operation for adjusting angles of the stators.

[5] In the positive displacement machine described in any one of [1] to [4], the second motor may include a second adjusting mechanism configured to adjust an angle of the second stator with respect to the second rotor, the angle being centered on the second rotation axis.

With such a configuration, since angles of the stators with respect to the rotors can be adjusted in each of the first motor and the second motor, it is possible to adjust angle phases of the motors more in detail. Therefore, it is possible to increase adjustment flexibility and further reduce vibration that occurs at the driving time of the positive displacement machine.

In the positive displacement machine described in any one of [1] to [5], the rotor may include: a shaft rotatable centering on a rotation axis; and a first magnet and a second magnet disposed in positions on opposite sides each other across the rotation axis in the shaft, magnetic poles of surfaces of the first magnet and the second magnet facing an outer side being different from each other, the stator may include a first phase coil, a second phase coil, and a third phase coil disposed at equal intervals from each other in a circumferential direction centered on the rotation axis, and a crossing angle of a first imaginary line connecting the first phase coil and the rotation axis and a second imaginary line connecting one magnet of the first magnet and the second magnet and the rotation axis may be same in the first motor and the second motor.

With such a configuration, since the crossing angle of the first imaginary line and the second imaginary line in the first motor and the crossing angle of the first imaginary line and the second imaginary line in the second motor are the same, it is possible to align an angle phase of the stator in the first motor and an angle phase of the stator in the second motor. Therefore, vibrations that occur in the motors can be offset each other. It is possible to reduce vibration that occurs at the driving time of the positive displacement machine.

[6] A compressor according to a second aspect of the present disclosure includes the positive displacement machine described in any one of [1] to [5]. The piston compresses gas flowing into the the pressure chamber.

With such a configuration, it is possible to achieve the same effects as the effects of the positive displacement machine according to the first aspect. Therefore, it is possible to configure a compressor capable of reducing vibration at a gas compression time.

[7] A cooling apparatus according to a third aspect of the present disclosure includes: the compressor described in [6] configured to compress working fluid in a gas phase; a condenser configured to condense the working fluid in the gas phase compressed by the compressor into the working fluid in a liquid phase; an expander configured to decompress the working fluid in the liquid phase condensed by the condenser and change a state of the working fluid to a state in which the liquid phase and the gas phase are mixed; and an evaporator coupled to a cooling target to transfer heat and configured to change the working fluid flowing from the expander to the working fluid in the gas phase with the heat transferred from the cooling target and discharge the changed working fluid in the gas phase to the compressor.

With such a configuration, it is possible to achieve the same effects as the effects of the compressor according to the second aspect. It is possible to configure a cooling apparatus capable of reducing vibration at an operation time.

[8] Electronic equipment according to a fourth aspect of the present disclosure includes the cooling apparatus described in [7].

With such a configuration, it is possible to achieve the same effects as the effects of the cooling apparatus according to the third aspect. It is possible to configure electronic equipment capable of reducing vibrating at an operation time.

What is claimed is:

1. A positive displacement machine comprising:
a housing including a tubular guide part in which a pressure chamber is provided;
a slide member including a piston disposed in the guide part, the slide member sliding in a first direction;
a coupling member coupled to the slide member and extending in a second direction intersecting the first direction;
a first rotating member coupled to one end portion of the coupling member and configured to rotate centering on a first rotation axis extending in the second direction;
a second rotating member coupled to another end of the coupling member and configured to rotate, centering on a second rotation axis extending along the second direction, in an opposite direction of a rotating direction of the first rotating member;
a first motor including a first rotor coupled to the first rotating member and configured to rotate centering on the first rotation axis, and a first stator disposed on an outer side of the first rotor when viewed along the first rotation axis; and
a second motor including a second rotor coupled to the second rotating member and configured to rotate centering on the second rotation axis, and a second stator disposed on an outer side of the second rotor when viewed along the second rotation axis, wherein
the first motor includes a first adjusting mechanism configured to adjust an angle of the first stator with respect to the first rotor, the angle being centered on the first rotation axis.

2. The positive displacement machine according to claim 1, further comprising
one driving circuit configured to control both the first motor and the second motor.

3. The positive displacement machine according to claim 1, further comprising
a fixing member configured to fix the first stator, the angle of which have been adjusted by the first adjusting mechanism.

4. The positive displacement machine according to claim 3, wherein
the fixing member is a screw, and
the first adjusting mechanism includes a long hole having an arcuate shape centered on the first rotation axis, the fixing member being inserted into the long hole.

5. The positive displacement machine according to claim 1, wherein
the second motor includes a second adjusting mechanism configured to adjust an angle of the second stator with respect to the second rotor, the angle being centered on the second rotation axis.

6. A compressor comprising the positive displacement machine according to claim 1, wherein
the piston is configured to compress gas flowing into the pressure chamber.

7. A cooling apparatus comprising:
the compressor according to claim 6 configured to compress working fluid in a gas phase;
a condenser configured to condense the working fluid in the gas phase compressed by the compressor into the working fluid in a liquid phase;
an expander configured to decompress the working fluid in the liquid phase condensed by the condenser and change the working fluid in the liquid phase to the working fluid in which the liquid phase and the gas phase are mixed; and
an evaporator coupled to a cooling target to transfer heat, the evaporator being configured to change the working fluid flowing from the expander to the working fluid in the gas phase with the heat transferred from the cooling target and discharge the changed working fluid in the gas phase to the compressor.

8. Electronic equipment comprising the cooling apparatus according to claim 7.
